(19) United States
(12) Patent Application Publication
(10) Pub. No.: US 2016/0163646 A1
(43) Pub. Date: Jun. 9, 2016

(54) STRAPPED CONTACT IN A SEMICONDUCTOR DEVICE

(71) Applicant: QUALCOMM Incorporated, San Diego, CA (US)

(72) Inventors: Haining Yang, San Diego, CA (US); Niladri Narayan Mojumder, San Diego, CA (US); Stanley Seungchul Song, San Diego, CA (US)

(21) Appl. No.: 14/670,280

(22) Filed: Mar. 26, 2015

Related U.S. Application Data
(60) Provisional application No. 62/088,249, filed on Dec. 5, 2014.

(51) Int. Cl. H01L 23/535; H01L 21/768; H01L 27/088

(52) U.S. Cl. CPC H01L 23/535; H01L 27/0886; H01L 21/76895

(57) ABSTRACT

An apparatus includes a first fin of a first transistor and a second fin of a second transistor. The apparatus also include a first contact coupled to the first fin and a second contact coupled to the second fin. The apparatus further includes a strapped contact coupled to the first contact and to the second contact.

### I. CROSS-REFERENCE TO RELATED APPLICATION

The present application claims priority from U.S. Provisional Patent Application No. 62/088,249, entitled “STRAPPED CONTACT,” filed Dec. 5, 2014, the content of which is incorporated by reference in its entirety.

### II. FIELD

The present disclosure is generally related to transistor technologies.

### III. DESCRIPTION OF RELATED ART

Advances in technology have resulted in smaller and more powerful computing devices. For example, there currently exist a variety of portable personal computing devices, including wireless computing devices, such as portable wireless telephones, personal digital assistants (PDAs), tablet computers, and paging devices that are small, lightweight, and easily carried by users. Many such computing devices include other devices that are incorporated therein. For example, a wireless telephone can also include a digital still camera, a digital video camera, a digital recorder, and an audio file player. Also, such computing devices can process executable instructions, including software applications, such as a web browser application that can be used to access the Internet and multimedia applications that utilize a still or video camera and provide multimedia playback functionality.

Electronic devices, such as wireless telephones, may include memories that include a memory array (e.g., a static random access memory (SRAM) array) including one or more memory cells. Traditional memory arrays may be fabricated using relatively large technology nodes (e.g., 16 nanometer (nm) technology nodes and above). Scaling down from 16 nm technology nodes may present challenges. For example, complementary metal oxide semiconductor (CMOS) scaling beyond 16 nm technology nodes (e.g., 10 nm and/or 7 nm technology nodes) may realize smaller device features using complex device integration and multiple (e.g., double or quadruple) mask patterning schemes. As a non-limiting example, four masks may be used to etch contacts for transistor source and drain regions in a 10 nm high density SRAM array. Thus, four lithography prints may be used to design the four masks, which may increase cost. Additionally, the relatively large number of lithography prints may subject the contacts to alignment errors with the source and drain regions. For example, overlaying four masks to perform different etches may increase the likelihood of alignment errors.

### IV. SUMMARY

Techniques for forming a strapped contact for source/drain regions in a high density circuit are disclosed. For example, a logic circuit fabricated according to a 10 nm technology node or a 7 nm technology node may include multiple transistors (e.g., a first transistor and an adjacent second transistor) in a relatively small die area. Each transistor may include a fin (e.g., a source/drain region) that is coupled to a contact (e.g., a metal contact or local interconnect). To form the contacts, a two mask process may be implemented to etch trenches through an interlayer dielectric to expose the fins, and the trenches may be filled with metal. The two mask process may include pattering a photo resist on the logic circuit and patterning a first mask (e.g., a hard mask) on the photo resist. A first etching process may be performed according to the first mask to expose a first fin of the first transistor (e.g., to form a first trench). After the first etching process, a second mask (e.g., a hard mask) may be patterned on the remaining photo resist and a second etching process may be performed according to the second mask to expose a second fin of the second transistor (e.g., to form a second trench). The first and second trenches may be filled with metal (e.g., tungsten, copper, silicide, etc.) to form first and second contacts on the first and second fins, respectively.

After the first and second contacts are formed, another photo resist may be patterned on the logic circuit and a third mask (e.g., a hard mask) may be patterned on the photo resist. The third mask may have an opening to expose the first and second contacts, and a third etching process may be performed to expose the first and second contacts (e.g., to form a third trench). The third trench may be filled with metal to form a “strapped contact” that couples the first contact to the second contact. As used herein, a “strapped contact” is a metal contact that electrically couples two or more fins directly or indirectly using other metal contacts. The strapped contact may extend the source/drain regions of the multiple transistors in the relatively small die area.

In a particular aspect, an apparatus includes a first fin of a first transistor and a second fin of a second transistor. The apparatus also include a first contact coupled to the first fin and a second contact coupled to the second fin. The apparatus further includes a strapped contact coupled to the first contact and to the second contact.

In another particular aspect, a method for forming contacts in a semiconductor device that is manufactured using a semiconductor manufacturing process of less than 16 nanometers (nm) includes patterning a first photo resist to apply a first pattern to a hard mask. The first pattern is designed to expose a first fin of a first transistor. The method also includes patterning a second photo resist to apply a second pattern to the hard mask. The second pattern is designed to expose a second fin of a second transistor. The method further includes etching a first trench through an interlayer dielectric according to the first pattern to expose the first fin and etching a second trench through the interlayer dielectric according to the second pattern to expose the second fin. The method further includes depositing metal into the first trench to form a first contact. The method also includes depositing metal into the second trench to form a second contact. The method further includes forming a strapped contact that is coupled to the first contact and to the second contact.

In another particular aspect, a non-transitory computer-readable medium includes instructions for forming contacts in a semiconductor device that is manufactured using a semiconductor manufacturing process of less than 16 nanometers (nm). The instructions, when executed by a processor, cause the processor to initiate patterning a first photo resist to apply a first pattern to a hard mask. The first pattern is designed to expose a first fin of a first transistor. The instructions are further executable to cause the processor to initiate patterning a second photo resist to apply a second pattern to the hard mask. The second pattern is designed to expose a second fin of a second transistor. The instructions are also executable to cause the processor to initiate etching a first trench through an interlayer dielectric according to the first pattern to expose the first fin and to initiate etching a second trench through the interlayer dielectric according to the second pattern to expose the second fin. The instructions are also executable to cause the processor to initiate depositing metal into the first trench to form a first contact and to initiate depositing metal into the second trench to form a second contact. The instructions are further executable to cause the processor to initiate forming a strapped contact that is coupled to the first contact and to the second contact.

In another particular aspect, an apparatus includes means for patterning a first photo resist to apply a first pattern to a hard mask. The first pattern is designed to expose a first fin of a first transistor. The apparatus also includes means for patterning a second photo resist to apply a second pattern to the hard mask. The second pattern is designed to expose a second fin of a second transistor. The apparatus further includes means for etching a first trench and a second trench through an interlayer dielectric. The first trench is etched according to the first pattern to expose the first fin, and the second trench is etched according to the second pattern to expose the second fin. The apparatus also includes means for depositing metal into the first trench to form a first contact and means for depositing metal into the second trench to form a second contact. The apparatus further includes means for forming a strapped contact that is coupled to the first contact and to the second contact.

One particular advantage provided by at least one of the disclosed embodiments is an ability to reduce alignment errors and cost while etching trenches for contacts to a source/drain region. For example, a reduced number of masks (e.g., two masks compared to four masks) may be used to etch trenches for source/drain contacts for sub-16 nm technology nodes. The reduced number of masks may decrease the likelihood of alignment errors caused by overlaying multiple masks to perform etches and may also reduce the process cost. Other aspects, advantages, and features of the present disclosure will become apparent after review of the entire application, including the following sections: Brief Description of the Drawings, Detailed Description, and the Claims.

### V. BRIEF DESCRIPTION OF THE DRAWINGS

FIG. 1A is a diagram illustrating a particular stage for forming a semiconductor device having a strapped contact;

FIG. 1B is a diagram illustrating another particular stage for forming the semiconductor device having the strapped contact;

FIG. 1C is a diagram illustrating another particular stage for forming the semiconductor device having the strapped contact;

FIG. 1D is a diagram illustrating another particular stage for forming the semiconductor device having the strapped contact;

FIG. 1E is a diagram illustrating another particular stage for forming the semiconductor device having the strapped contact;

FIG. 1F is a diagram illustrating another particular stage for forming the semiconductor device having the strapped contact;

FIG. 1G is a diagram illustrating another particular stage for forming the semiconductor device having the strapped contact;

FIG. 2 is a diagram illustrating a cross-sectional view of a portion of the semiconductor device formed according to the techniques of FIGS. 1A-1G;

FIG. 3 is a flow chart of a particular illustrative embodiment of a method for forming a semiconductor device having a strapped contact;

FIG. 4 is a block diagram of a device that includes a semiconductor device designed based on techniques described with respect to FIG. 1A-FIG. 3; and

FIG. 5 is a data flow diagram of a particular illustrative embodiment of a manufacturing process to manufacture electronic devices based on techniques described with respect to FIG. 1A-FIG. 3.

### VI. DETAILED DESCRIPTION

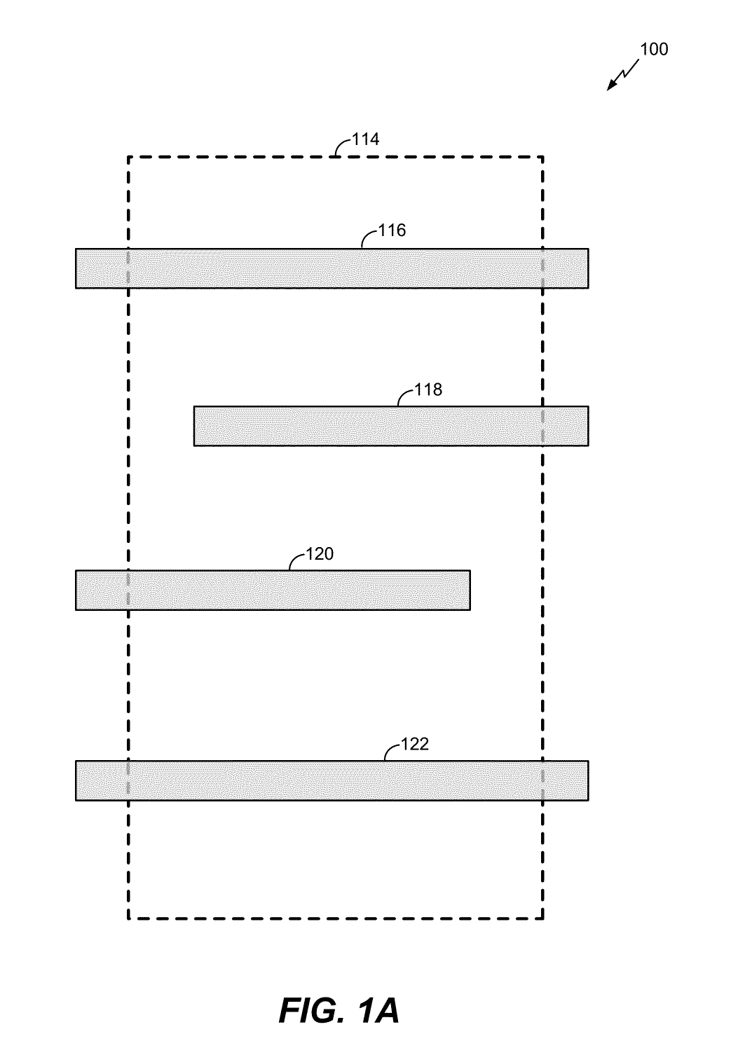

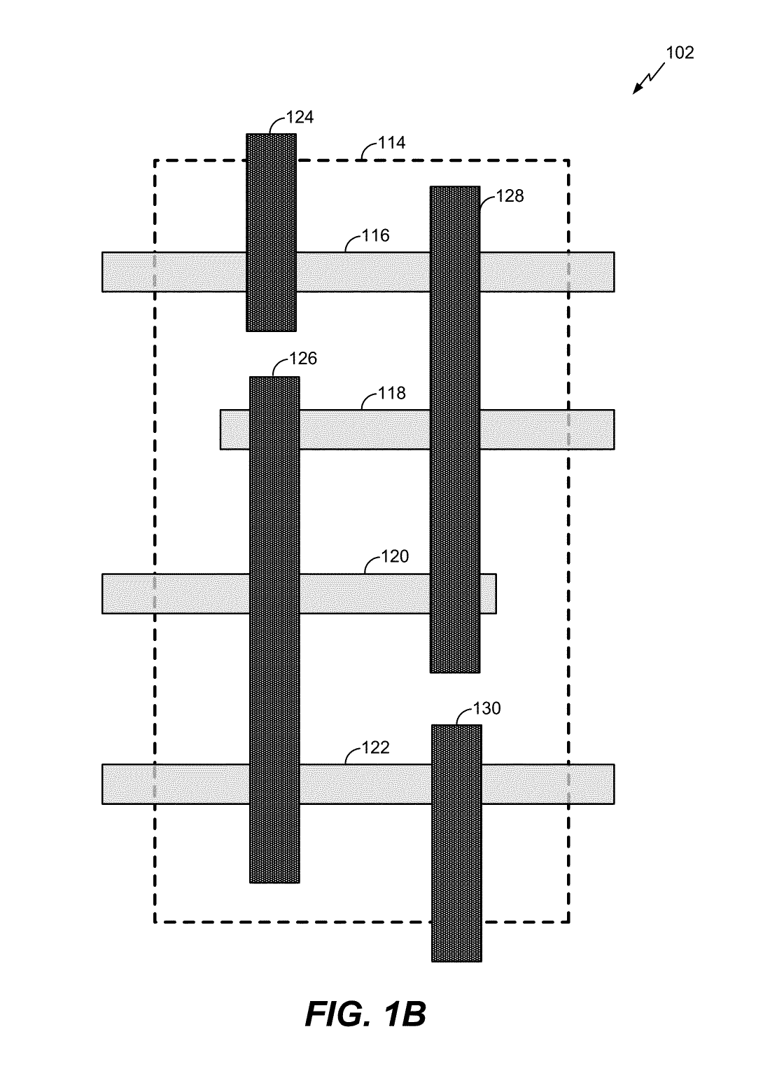

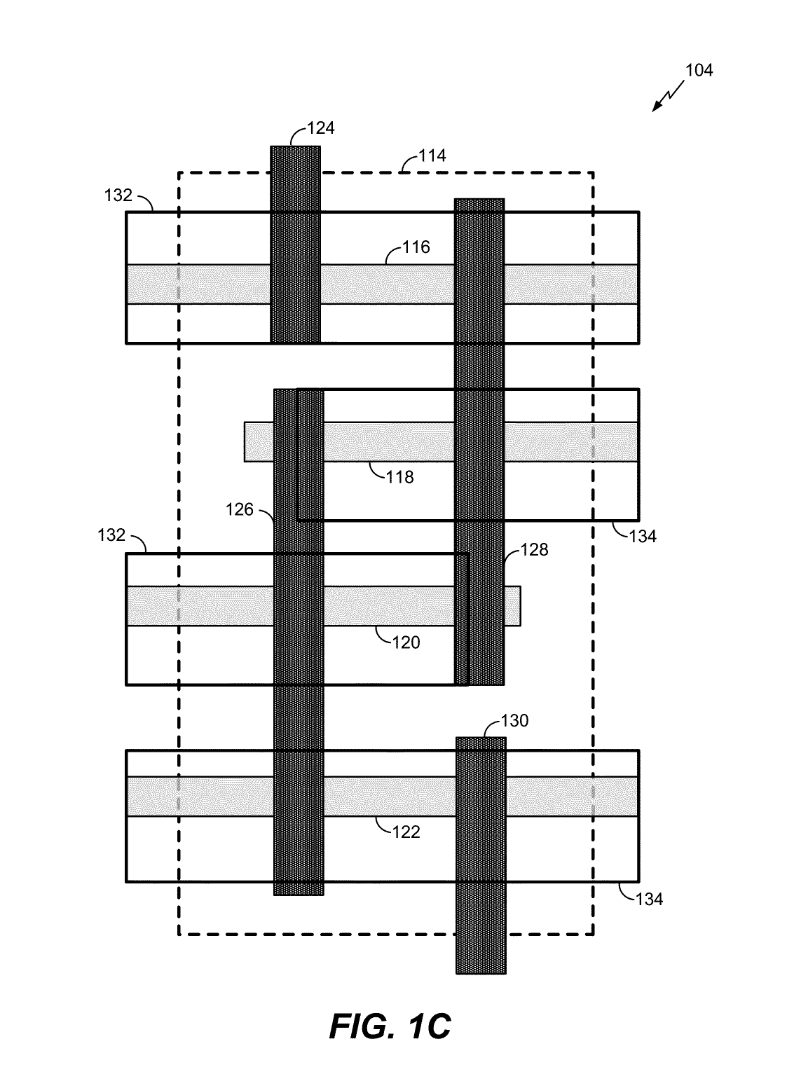

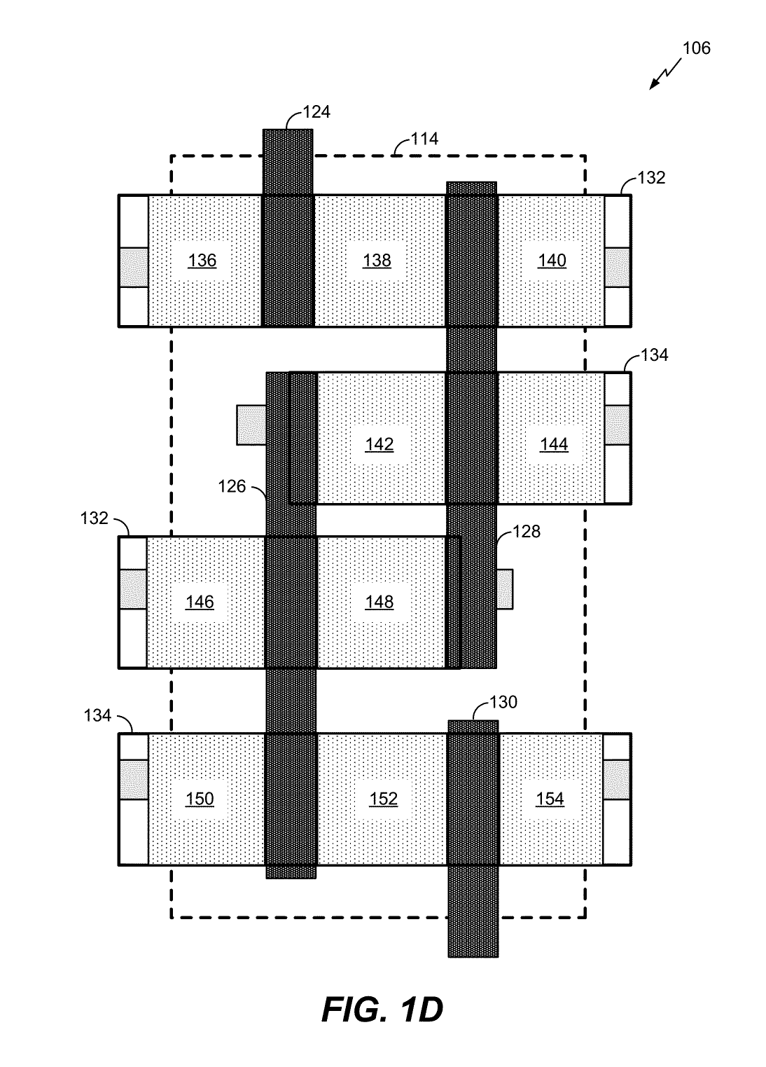

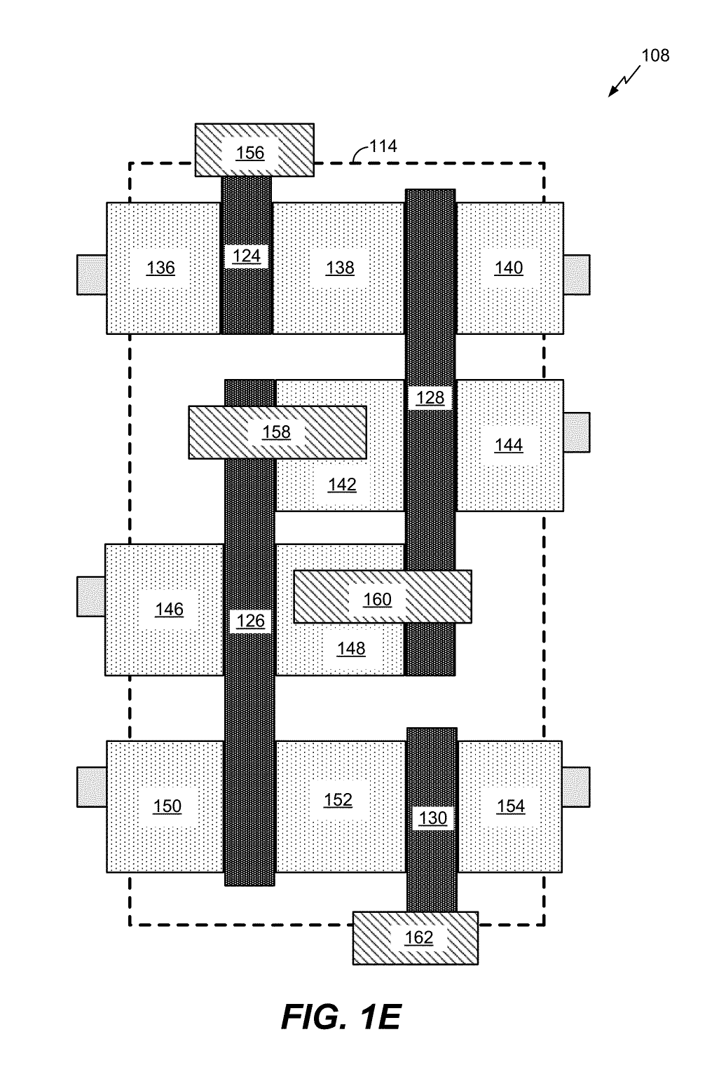

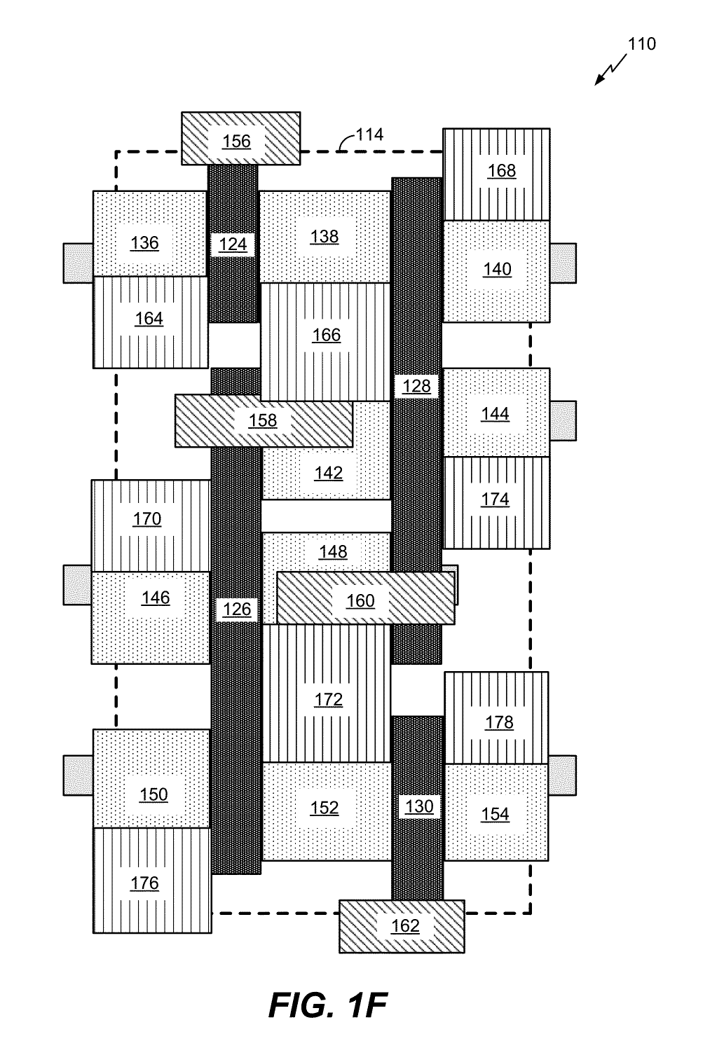

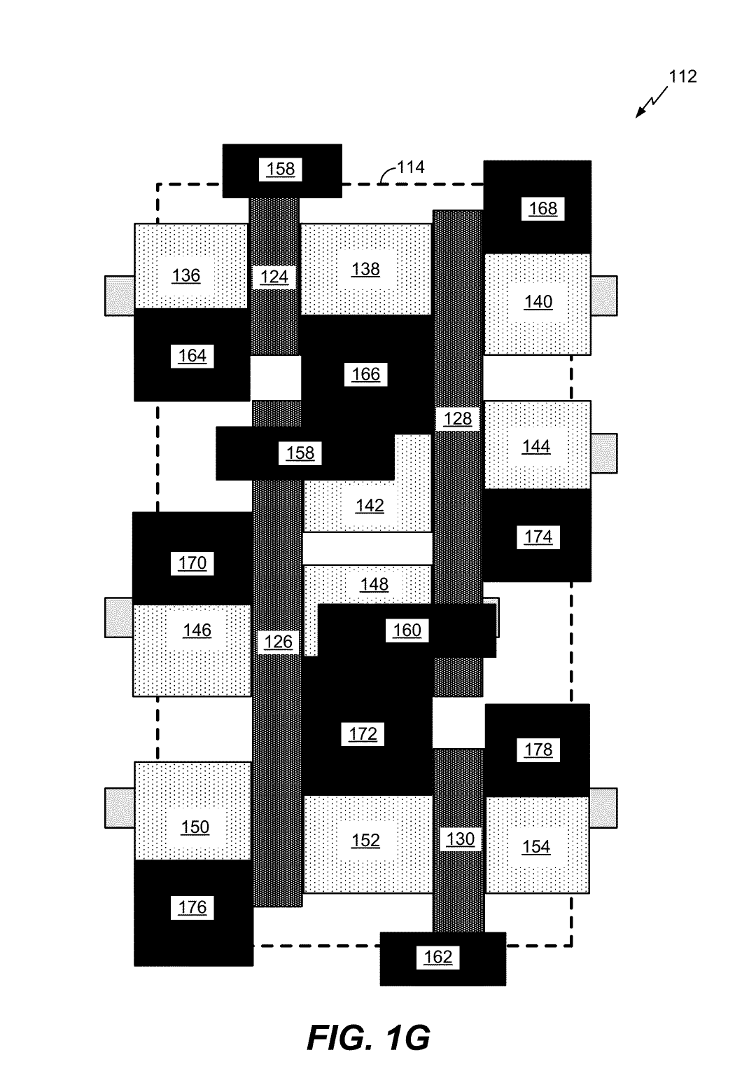

Referring to FIG. 1A, a diagram illustrating a particular stage 100 for forming a semiconductor device having a strapped contact is shown. In the illustrative embodiment, the semiconductor device may include a static random access memory (SRAM) bit cell 114 (e.g., a six-transistor (6T) SRAM bit cell). However, illustrative embodiment should not be construed as limiting. For example, in alternate embodiments, the semiconductor device may include alternative logic circuits (e.g., dynamic random access memory (DRAM) cells, magnetic random access memory (MRAM) cells, etc.) Forming the semiconductor device having a strapped contact may accommodate high density architectures where fins (e.g., source and drain regions) from different transistors are relatively close. For example, as described in greater detail below, the techniques described herein may accommodate sub-16 nm technology nodes (e.g., 10 nm technology nodes and/or 7 nm technology nodes) by increasing fin spacing (e.g., source/drain region spacing) and improving contact alignment of source/drain regions of different transistors.

At the stage 100 illustrated in FIG. 1A, multiple fins 116, 118, 120, 122 may be etched from a substrate of the SRAM bit cell 114. For example, a first fin 116 may be etched from the substrate, a second fin 118 may be etched from the substrate, a third fin 120 may be etched from the substrate, and a fourth fin 122 may be etched from the substrate. In a particular embodiment, the substrate is a silicon substrate. Thus, each fin 116, 118, 120, 122 may be a silicon fin.

To etch each fin 116, 118, 120, 122, a photo resist may be formed on a surface of the substrate, a hard mask may be placed on top of the photo resist, and the fins 116, 118, 120, 122 may be etched according to a design pattern of the hard mask. The fins 116, 118, 120, 122 may be etched according to a two mask litho-etch-litho-etch (LELE) process, a self-aligned double patterning (SADP) process, or a self-aligned quadruple patterning (SAQP) process.

Referring to FIG. 1B, a diagram illustrating another particular stage 102 for forming the semiconductor device having the strapped contact is shown. At the stage 102, a first gate 124 may be formed over the first fin 116, a second gate 126 may be formed over the second, third, and fourth fins 118, 120, 122, a third gate 128 may be formed over the first, second, and third fins 116, 118, 120, and a fourth gate 130 may be formed over the fourth fin 122. In a particular embodiment, each gate 124, 126, 128, 130 may be a metal gate. In an alternative embodiment, each gate 124, 126, 128, 130 may be a poly gate.

The gates 124, 126, 128, 130 may be formed using a replacement gate damascene process. For example, poly silicon (not shown) may be deposited in the SRAM bit cell 114 as a “dummy gate”. To illustrate, two vertical lines of poly silicon may be deposited in the SRAM bit cell 114 based on the layout of the gates 124, 126, 128, 130 depicted in FIG. 1B. For example, a first vertical line of poly silicon formed according to the pattern of the first and second gates 124, 126 may be deposited in the SRAM bit cell 114, and a second vertical line of poly silicon formed according to the pattern of the third and fourth gates 128, 130 may be deposited in the SRAM bit cell 114. After the first and second vertical lines of poly silicon are formed, the first line of poly silicon may be cut to generate a first dummy gate (based on the first gate 124) and a second dummy gate (based on the second gate 126). Additionally, the second line of poly silicon may be cut to generate a third dummy gate (based on the third gate 128) and a fourth dummy gate (based on the fourth gate 130).

After the dummy gates have been formed, a spacer material (not shown) may be formed along the sidewalls of the dummy gates. In a particular embodiment, the spacer material may include silicon nitride. After the spacer material is formed along the sidewalls of the dummy gates, an interlayer dielectric (ILD) (not shown) may be deposited into the SRAM bit cell 114. In a particular embodiment, the ILD may be comprised of silicon oxide. The ILD may undergo a chemical mechanical polishing (CMP) process to expose the poly silicon dummy gates.

After the CMP process, the poly silicon dummy gates may be removed. For example, the poly silicon dummy gates may be removed via a wet etching process to form gate trenches. The gate trenches may be filled with a high dielectric constant (high-k) dielectric layer (not shown). After the high-k dielectric layer is deposited into the gate trenches, the gates 124, 126, 128, 130 may be deposited on top of the high-k dielectric layer.

The first fin 116 and the first gate 124 are a source/drain region and a gate, respectively, of a first transistor in the SRAM bit cell 114. The first fin 116 and the third gate 128 are a source/drain region and a gate, respectively, of a second transistor in the SRAM bit cell 114. The second fin 118 and the third gate 128 are a source/drain region and a gate, respectively, of a third transistor in the SRAM bit cell 114. The third fin 120 and the second gate 126 are a source/drain region and a gate, respectively, of a fourth transistor in the SRAM bit cell 114. The fourth fin 122 and the second gate 126 are a source/drain region and a gate, respectively, of a fifth transistor in the SRAM bit cell 114. The fourth fin 122 and the fourth gate 130 are a source/drain region and a gate, respectively, of a sixth transistor in the SRAM bit cell 114.

Referring to FIG. 1C, a diagram illustrating another particular stage 104 for forming the semiconductor device having the strapped contact is shown. At stage 104, a two mask process (as opposed to a four mask process) may be implemented to open (e.g., “expose”) source and drain regions of the fins 116, 118, 120, 122 after ILD deposition and planarization.

To illustrate, a first photo resist may be placed on a surface of the SRAM bit cell 114 to apply a first pattern to a hard mask. The first photo resist may be patterned along the first fin 116 and the third fin 120. For example, openings 132 in the first pattern of the first photo resist may be designed to expose the first fin 116 and the third fin 120 (e.g., non-adjacent fins). After the first photo resist is patterned to transfer the first pattern to underline the hard mask, the first photo resist may be stripped.

Similar masking techniques may be applied to expose the second fin 118 and the fourth fin 122. To illustrate, a second photo resist may be placed on the surface of the SRAM bit cell 114 to apply a second pattern to the hard mask. The second photo resist may be patterned along the second fin 118 and the fourth fin 122. For example, openings 134 in the second pattern of the second photo resist may be designed to expose the second fin 118 and the fourth fin 122 (e.g., non-adjacent fins). After the second photo resist is patterned to transfer the second pattern to underline the hard mask, the second photo resist may be stripped.

After the first and second photo resist are patterned, trenches may be etched into the openings 132, 134. For example, a trench may be etched into the ILD to expose the first fin 116, and a trench may be etched into the ILD to expose the third fin 120. Additionally, a trench may be etched into the ILD to expose the second fin 118, and a trench may be etched into the ILD to expose the fourth fin 122.

Because the fins (e.g., the sources and drains) for different transistors are relatively close in sub-16 nm technology nodes (e.g., 10 nm technology nodes and/or 7 nm technology nodes), the two mask process illustrated in FIG. 1C may reduce alignment errors based on lithography printing that may be attributed to a four mask approach. To illustrate, there may be relatively small spacing between adjacent fins (e.g., the first and second fins 116, 118, the second and third fins 118, 120, and the third and fourth fins 120, 122). The two mask process illustrated in FIG. 1C may concurrently etch through the ILD to non-adjacent fins. Etching through the ILD at non-adjacent fins may relax process control constraints during lithography printing of the mask because the distance between non-adjacent fins is relatively large compared to the distance between adjacent fins. Additionally, misalignment errors and costs (that may otherwise be present in a four mask process) may be reduced. For example, the four mask process may include lithography printing for four masks as compared to lithography printing for two masks, and thus the four mask process may be more susceptible to alignment errors (e.g., errors corresponding to the location of the openings in the masks) because of mask overlay.

Referring to FIG. 1D, a diagram illustrating another particular stage 106 for forming the semiconductor device having the strapped contact is shown. At stage 106, the trenches etched according to the openings 132, 134 may be filled with metal to create source and drain contacts (e.g., metal contacts). The metal contacts may be comprised of tungsten, copper, silicide, or any other metal.

For example, a first metal contact 136, a second metal contact 138, and a third metal contact 140 may be deposited on the source/drain regions of the first fin 116 (e.g., deposited into the ILD opening 132). The metal contacts 136, 138, 140 may be separated from the gates 124, 128 via the spacer material (not shown) along the sidewalls of the gates 124, 128. Additionally, a fourth metal contact 142 and a fifth metal contact 144 may be deposited on the source/drain regions of the second fin 118 (e.g., deposited into the ILD opening 134). Each metal contact 142, 144 may be separated from the gates 126, 128 via the spacer material (not shown) along the sidewalls of the gates 126, 128. A sixth metal contact 146 and a seventh metal contact 148 may be deposited on the source/drain regions of the third fin 120 (e.g., deposited into the ILD opening 132). Each metal contact 146, 148 may be separated from the gates 126, 128 via the spacer material (not shown) along the sidewalls of the gates 126, 128. An eighth metal contact 150, a ninth metal contact 152, and a tenth metal contact 154 may be deposited on the source/drain regions of the fourth fin 122 (e.g., deposited into the ILD opening 134). Each metal contact 150, 152, 154 may be separated from the gates 126, 130 via the spacer material (not shown) along the sidewalls of the gates 126, 130.

The metal contacts in FIG. 1D may operate as local interconnects for the source/drain regions. For example, the metal contacts may provide a conductive path to the source/drain regions of the fins in the SRAM bit cell 114. After the metal contacts are deposited, the metal contacts may be planarized.

Referring to FIG. 1E, a diagram illustrating another particular stage 108 for forming the semiconductor device having the strapped contact is shown. At stage 108, trenches for gate contacts may be etched on the gates 124, 126, 128, 130 of the SRAM bit cell 114. For example, a trench for a first gate contact 156 may be etched through the ILD to the first gate 124, a trench for a second gate contact 158 may be etched through the ILD to the second gate 126, a trench for a third gate contact 160 may be etched through the ILD to the third gate 128, and a trench for a fourth gate contact 162 may be etched through the ILD to the fourth gate 130.

The trenches for the gate contacts 156, 158, 160, 162 may be etched using a single mask process or a two mask process. For example, during a single mask process, a photo resist may be applied to a surface of the SRAM bit cell 114. A single mask (e.g., a hard mask) having openings at the locations of the gate contacts 156, 158, 160, 162 may be patterned on the photo resist. After the single mask is patterned, trenches may be etched into the openings of the single mask. For example, trenches may be etched into the ILD at areas where the gate contacts 156, 158, 160, 162 illustrated in FIG. 1E are located.

During a two mask process, a photo resist may be applied to a surface of the SRAM bit cell 114 and a first mask (e.g., a hard mask) having openings at the locations of the first and third gate contacts 156, 160 may be patterned on the photo resist. After the first mask is patterned, trenches may be etched into the openings of the first mask. For example, trenches may be etched into the ILD at areas where the first and third gate contacts 156, 160 illustrated in FIG. 1E are located. After the trenches are etched into the ILD, a second mask (e.g., a hard mask) having openings at the locations of the second and fourth gate contacts 158, 162 may also be patterned on the photo resist. After the second mask is patterned, trenches may be etched into the openings of the second mask. For example, trenches may be etched into the ILD at areas where the second and fourth gate contacts 158, 162 illustrated in FIG. 1E are located.

Referring to FIG. 1F, a diagram illustrating another particular stage 110 for forming the semiconductor device having the strapped contact is shown. At stage 110, trenches for strapped contacts 164-176 may be etched to couple a metal contact (e.g., a source/drain contact) of one transistor in the SRAM bit cell 114 to a metal contact of another transistor in the SRAM bit cell 114.

For example, trenches for the contacts 164-176 may be etched through the ILD to the metal contacts 136-154 in the SRAM bit cell 114. To etch the trenches for the contacts 164-176, a photo resist may be applied to a surface of the SRAM bit cell 114 and a mask (e.g., a hard mask) having openings at the locations of the contacts 164-176 may be patterned on the photo resist. After the mask is patterned, trenches may be etched into the openings of the mask. For example, trenches may be etched into the ILD at areas where the contacts 164-176 illustrated in FIG. 1F are located.

Referring to FIG. 1G, a diagram illustrating another particular stage 112 for forming the semiconductor device having the strapped contact is shown. At stage 112, the trenches etched in stages 108 and 110 may be filled with metal to form one or more strapped contacts. For example, metal may be deposited into the trenches to form the gate contacts 156, 158, 160, 162 and the contacts 164-176. In a particular embodiment, the metal deposited into the trenches to form the gate contacts 156, 158, 160, 162 and the contacts 164-176 may comprise tungsten, copper, silicide, or any other metal. After the metal is deposited into the trenches, the SRAM bit cell 114 may undergo planarization to smooth the surface.

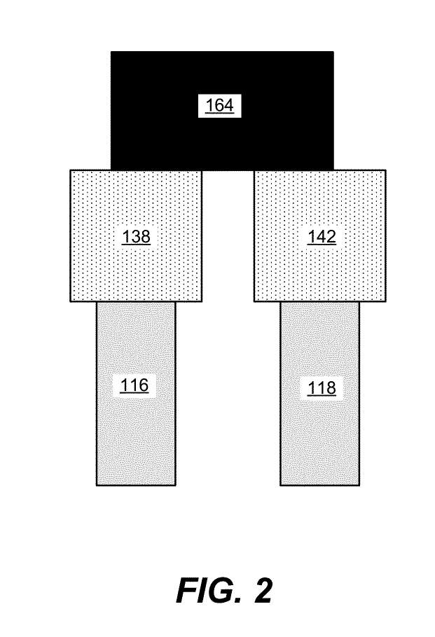

In the embodiment illustrated in FIG. 1G, the contact 166 may be a “strapped contact” that couples the second metal contact 138 to the fourth metal contact 142. For example, the contact 166 may couple the source/drain of the first transistor (e.g., the first fin 116) to the source/drain of the third transistor (e.g., the second fin 118). A cross-sectional view of a strapped contact feature is described below with respect to FIG. 2. Additionally, the contact 172 may be a strapped contact that couples the seventh metal contact 148 to the ninth metal contact 152. For example, the contact 172 may couple the source/drain of the fourth transistor (e.g., the third fin 120) to the source/drain of the fifth transistor (e.g., the fourth fin 122).

Thus, the strapped contacts may form connections among source/drain regions of different transistors (e.g., different fins) in a relatively dense circuit (e.g., a circuit manufactured according to a 10 nm technology node and/or a 7 nm technology node).

Referring to FIG. 2, a cross-sectional view of a portion of the semiconductor device formed according to the techniques of FIGS. 1A-1G is shown. The cross-sectional view depicts the first fin 116, the second fin 118, the second metal contact 138, the fourth metal contact 142, and the contact 164 (e.g., the “strapped” contact).

The illustrated portion of the first fin 116 may correspond to a source/drain region of the first transistor in the SRAM bit cell 114 (e.g., the transistor having the first fin 116 and the first gate 124). The illustrated portion of the second fin 118 may correspond to a source/drain region of the fourth transistor in the SRAM bit cell 114 (e.g., the transistor having the second fin 118 and the second gate 126).

The second metal contact 138 may be deposited on the first fin 116 according to the techniques described with respect to FIG. 1D. Additionally, the fourth metal contact 142 may be deposited on the second fin 118 according to the techniques described with respect to FIG. 1D. The contact 164 may be deposited on top of the second metal contact 138 and on top of the fourth metal contact 142 according to the techniques described with respect to FIGS. 1F-1G. Thus, the contact 164 may form connections among source/drain regions of the first transistor and the fourth transistor in the SRAM cell 114.

Thus, in a relatively dense circuit (e.g., a circuit manufactured according to a 10 nm technology node and/or a 7 nm technology node) where a size of the source/drain regions is reduced and/or a where a single source/drain region (e.g., a single fin) is used for multiple transistors, the strapped contact (e.g., the contact 164) may extend source/drain regions based on the contact 164.

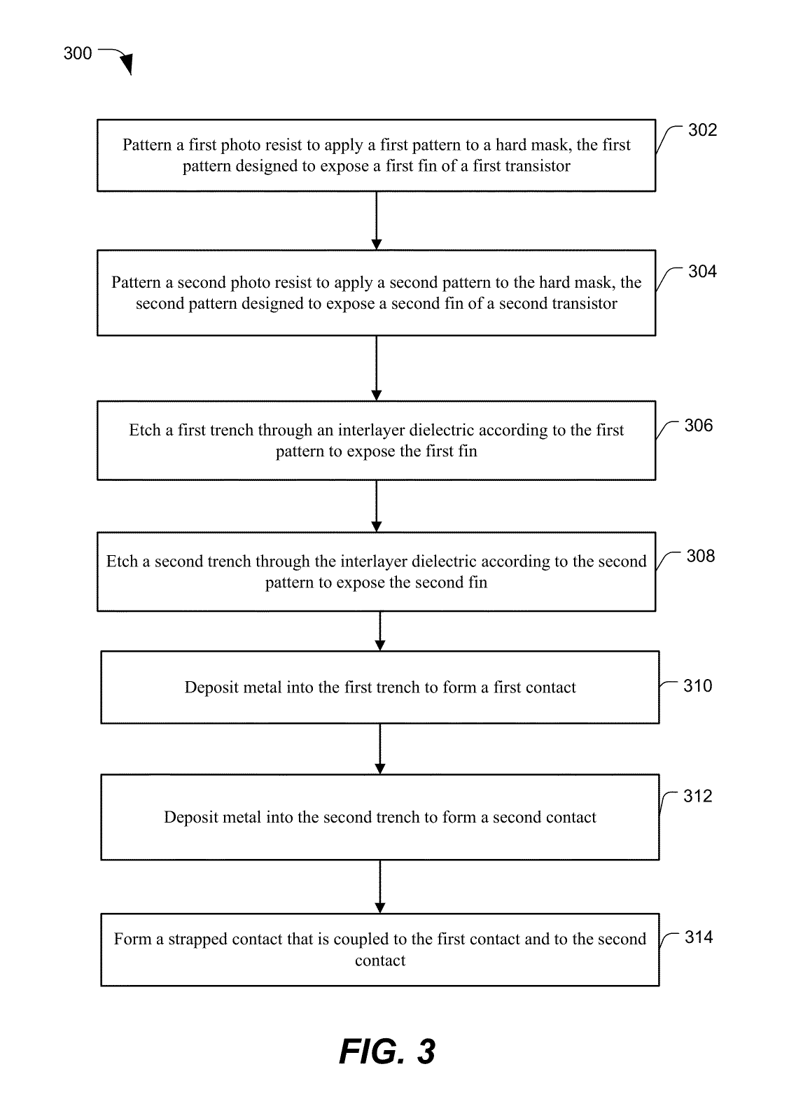

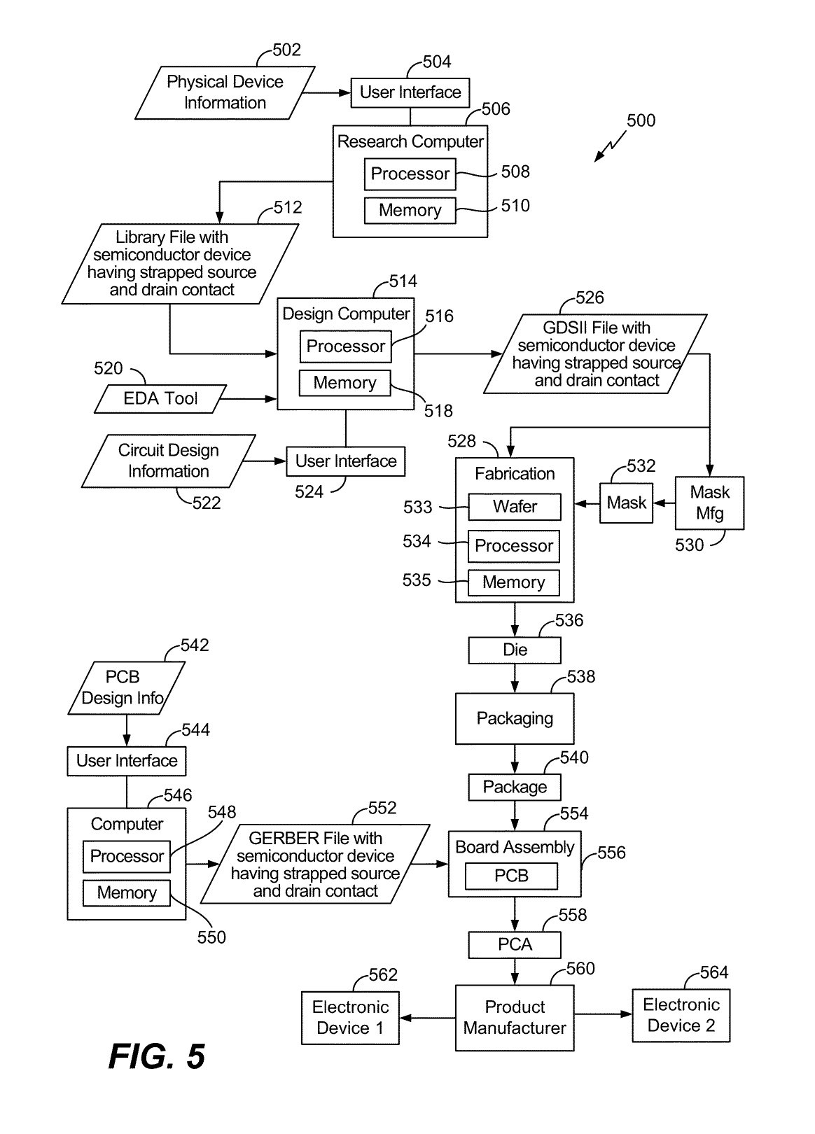

Referring to FIG. 3, a flowchart of a particular illustrative embodiment of a method 300 for forming a semiconductor device having a strapped contact is shown. The method 300 may be performed using the manufacturing equipment described with respect to FIG. 5.

The method 300 includes patterning a first photo resist to apply a first pattern to a hard mask, at 302. The first pattern may be designed to expose a first fin of a first transistor. For example, referring to FIG. 1C, the first photo resist may be patterned on a surface of the SRAM bit cell 114 to expose the first fin 116 (e.g., the fin of the “first transistor” according to the method 300). For example, openings in the first pattern may be designed to expose the first fin 116. After the first photo resist is patterned to transfer the first pattern to underline the hard mask, the first photo resist may be stripped.

A second photo resist may be patterned to apply a second pattern to the hard mask, at 304. The second pattern may be designed to expose a second fin of a second transistor. For example, referring to FIG. 1C, the second photo resist may be patterned on the surface of the SRAM bit cell 114 to expose the second fin 118 (e.g., the fin of the “second transistor” according to the method 300). For example, openings in the second pattern may be designed to expose the second fin 118. After the second photo resist is patterned to transfer the second pattern to underline the hard mask, the second photo resist may be stripped.

A first trench may be etched through an interlayer dielectric according to the first pattern to expose the first fin, at 306. For example, referring to FIG. 1C, a trench may be etched into the ILD to expose the first fin 116. A second trench may be etched through the interlayer dielectric according to the second pattern to expose the second fin, at 308. For example, referring to FIG. 1C, another trench may be etched into the ILD to expose the second fin 118.

Metal may be deposited into the first trench to form a first contact, at 310. For example, referring to FIG. 1D, metal may be deposited into the trench etched to expose the first fin 116 to form the metal contact 138 (e.g., the “first contact” according to the method 300). In a particular embodiment, tungsten, copper, silicide, or any other metal may be deposited into the trench to form the metal contact 138.

Metal may be deposited into the second trench to form a second contact, at 312. For example, referring to FIG. 1D, metal may be deposited into the trench etched to expose the second fin 118 to form the metal contact 142 (e.g., the “second contact” according to the method 300). In a particular embodiment, tungsten, copper, silicide, or any other metal may be deposited into the trench to form the metal contact 142.

A strapped contact that is coupled to the first contact and to the second contact may be formed, at 314. For example, referring to FIGS. 1F-1G, a trench for the contact 164 (e.g., the “strapped contact” according to the method 300) may be etched through the ILD to the metal contacts 138, 142 in the SRAM bit cell 114. To etch the trench for the contact 164, a photo resist may be applied to a surface of the SRAM bit cell 114 and a mask (e.g., a hard mask) having an opening at the location of the contact 164 may be patterned on the photo resist. After the mask is patterned, the trench may be etched into the opening of the mask. For example, the trench may be etched into the ILD at the area where the contact 164 illustrated in FIG. 1F is located. After etching the trench, the trench may be filled with metal to form the contact 166. In a particular embodiment, the metal deposited into the trench to form the contact 166 may comprise tungsten, copper, silicide, or any other metal. After the metal is deposited into the trench, the SRAM bit cell 114 may undergo planarization.

The method 300 of FIG. 3 may utilize a two mask process to etch trenches for fin contacts (e.g., source and drain contacts) for transistors that are relatively close in sub-16 nm technology nodes (e.g., 10 nm technology nodes and/or 7 nm technology nodes). The two mask process may reduce alignment errors based on lithography printing that may be attributed to a four mask approach. For example, there may be relatively small spacing between adjacent fins (e.g., the first and second fins 116, 118). The two mask process may relax process control constraints during lithography printing of the mask. To illustrate, misalignment errors and costs (that may otherwise be present in a four mask process) may be reduced. For example, the four mask process may include lithography printing for four masks as compared to lithography printing for two masks, and thus the four mask process may be more susceptible to alignment errors (e.g., errors corresponding to the location of the openings in the masks) because of mask overlay. The method 300 may also form the contact 164 (e.g., the strapped contact) to extend the fins 116, 118 of multiple transistors in the relatively dense circuit.

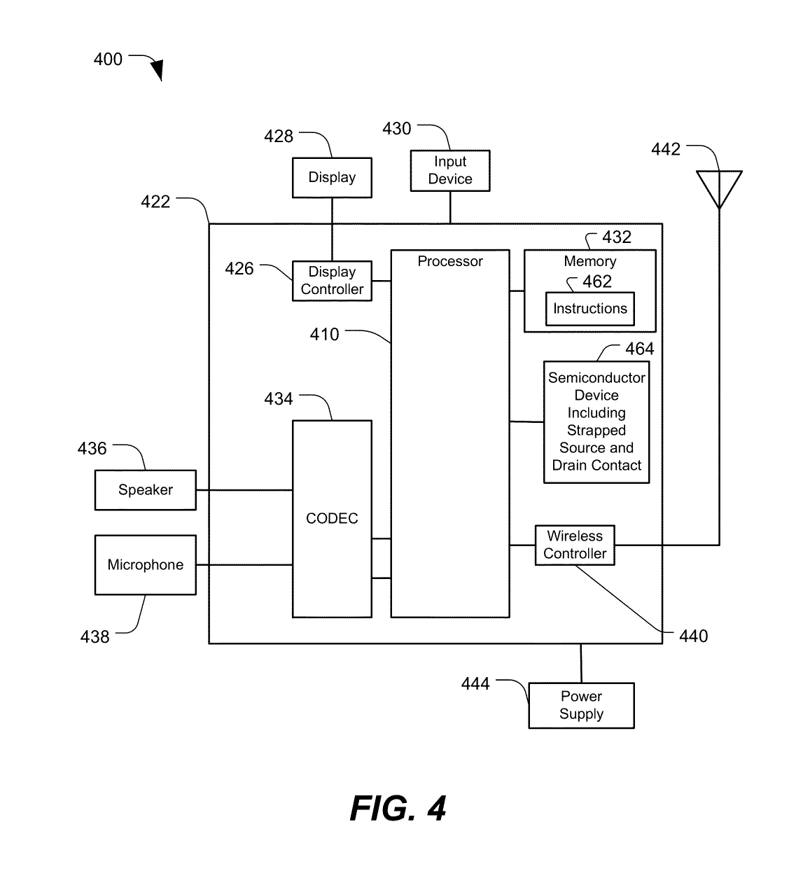

Referring to FIG. 4, a block diagram of a particular illustrative embodiment of an electronic device is depicted and generally designated 400. The electronic device 400 includes a processor 410, such as a digital signal processor (DSP) or a central processing unit (CPU), coupled to a memory 432.

The processor 410 may be coupled to a semiconductor device 464 that includes a strapped contact. As a non-limiting example, the semiconductor device 464 may include the SRAM bit cell 114. To illustrate, the semiconductor device 464 may be an SRAM array that includes multiple bit cells, including the SRAM bit cell 114. Thus, the semiconductor device 464 may include a strapped contact that couples together fins from different transistors in the SRAM bit cell 114. It should be noted that although FIG. 4 illustrates use of the semiconductor device 464 coupled to the processor 410, this is not to be considered limiting. Semiconductor devices in accordance with the present disclosure, such as the semiconductor device 464, may be included in any type of memory of any type of electronic device.

FIG. 4 shows a display controller 426 that is coupled to the processor 410 and to a display 428. A coder/decoder (CODEC) 434 can also be coupled to the processor 410. A speaker 436 and a microphone 438 can be coupled to the CODEC 434. FIG. 4 also indicates that a wireless controller 440 can be coupled to the processor 410 and to an antenna 442. In a particular embodiment, the processor 410, the display controller 426, the memory 432, the CODEC 434, and the wireless controller 440 are included in a system-in-package or system-on-chip device (e.g., mobile station modem (MSM)) 422. In a particular embodiment, an input device 430 and a power supply 444 are coupled to the system-on-chip device 422. Moreover, in a particular embodiment, as illustrated in FIG. 4, the display 428, the input device 430, the speaker 436, the microphone 438, the antenna 442, and the power supply 444 are external to the system-on-chip device 422. However, each of the display 428, the input device 430, the speaker 436, the microphone 438, the antenna 442, and the power supply 444 can be coupled to a component of the system-on-chip device 422, such as an interface or a controller.

Although the semiconductor device 464 is depicted in the electronic device 400 of FIG. 4, in other embodiments, the semiconductor device 464 may be included in other devices. As non-limiting examples, the semiconductor device 464 may be included in a set top box, an entertainment unit, a navigation device, a personal digital assistant (PDA), a monitor, a computer monitor, a television, a tuner, a radio, a satellite radio, a music player, a digital music player, a portable music player, a video player, a digital video player, a digital video disc (DVD) player, a portable digital video player, a vehicle, or any other device.

The foregoing disclosed devices and functionalities may be designed and configured into computer files (e.g., RTL, GDSII, GERBER, etc.) stored on computer-readable media. Some or all such files may be provided to fabrication handlers to fabricate devices based on such files. Resulting products include wafers that are then cut into dies and packaged into chips. The chips are then employed in devices described above. FIG. 5 depicts a particular illustrative embodiment of an electronic device manufacturing process 500.

Physical device information 502 is received at the manufacturing process 500, such as at a research computer 506. The physical device information 502 may include design information representing at least one physical property of a semiconductor device, such as a physical property of the SRAM bit cell 114, an array of bit cells having one or more strapped contacts manufactured according to a sub-16 nm technology node, or any other semiconductor device having a strapped contact manufactured according to a sub-16 nm technology node. For example, the physical device information 502 may include physical parameters, material characteristics, and structure information that is entered via a user interface 504 coupled to the research computer 506. The research computer 506 includes a processor 508, such as one or more processing cores, coupled to a computer-readable medium such as a memory 510. The memory 510 may store computer-readable instructions that are executable to cause the processor 508 to transform the physical device information 502 to comply with a file format and to generate a library file 512.

In a particular embodiment, the library file 512 includes at least one data file including the transformed design information. For example, the library file 512 may include a library of semiconductor devices, including the SRAM bit cell 114, an array of bit cells having one or more strapped contacts manufactured according to a sub-16 nm technology node, or any other semiconductor device having a strapped contact manufactured according to a sub-16 nm technology node, provided for use with an electronic design automation (EDA) tool 520.

The library file 512 may be used in conjunction with the EDA tool 520 at a design computer 514 including a processor 516, such as one or more processing cores, coupled to a memory 518. The EDA tool 520 may be stored as processor executable instructions at the memory 518 to enable a user of the design computer 514 to design the SRAM bit cell 114, an array of bit cells having one or more strapped contacts manufactured according to a sub-16 nm technology node, or any other semiconductor device having a strapped contact manufactured according to a sub-16 nm technology node, using the library file 512. For example, a user of the design computer 514 may enter circuit design information 522 via a user interface 524 coupled to the design computer 514. The circuit design information 522 may include design information representing at least one physical property of a semiconductor device, such as the SRAM bit cell 114, an array of bit cells having one or more strapped contacts manufactured according to a sub-16 nm technology node, or any other semiconductor device having a strapped contact manufactured according to a sub-16 nm technology node. To illustrate, the circuit design property may include identification of particular circuits and relationships to other elements in a circuit design, positioning information, feature size information, interconnection information, or other information representing a physical property of an electronic device.

The design computer 514 may be configured to transform the design information, including the circuit design information 522, to comply with a file format. To illustrate, the file formation may include a database binary file format representing planar geometric shapes, text labels, and other information about a circuit layout in a hierarchical format, such as a Graphic Data System (GDSII) file format. The design computer 514 may be configured to generate a data file including the transformed design information, such as a GDSII file 526 that includes information describing the SRAM bit cell 114, an array of bit cells having one or more strapped contacts manufactured according to a sub-16 nm technology node, or any other semiconductor device having a strapped contact manufactured according to a sub-16 nm technology node, in addition to other circuits or information. To illustrate, the data file may include information corresponding to the SRAM bit cell 114, an array of bit cells having one or more strapped contacts manufactured according to a sub-16 nm technology node, or any other semiconductor device having a strapped contact manufactured according to a sub-16 nm technology node.

The GDSII file 526 may be received at a fabrication process 528 to manufacture a semiconductor device described with reference to FIGS. 1A-4 according to transformed information in the GDSII file 526. For example, a device manufacture process may include providing the GDSII file 526 to a mask manufacturer 530 to create one or more masks, such as masks to be used with photolithography processing, illustrated in FIG. 5 as a representative mask 532. The mask 532 may be used during the fabrication process to generate one or more wafers 533, which may be tested and separated into dies, such as a representative die 536. The die 536 includes a circuit including the SRAM bit cell 114, an array of bit cells having one or more strapped contacts manufactured according to a sub-16 nm technology node, or any other semiconductor device having a strapped contact manufactured according to a sub-16 nm technology node.

In a particular embodiment, the fabrication process 528 may be initiated by or controlled by a processor 534. The processor 534 may access a memory 535 that includes executable instructions such as computer-readable instructions or processor-readable instructions. The executable instructions may include one or more instructions that are executable by a computer, such as the processor 534.

The fabrication process 528 may be implemented by a fabrication system that is fully automated or partially automated. For example, the fabrication process 528 may be automated and may perform processing steps according to a schedule. The fabrication system may include fabrication equipment (e.g., processing tools) to perform one or more operations to form an electronic device.

The fabrication system may have a distributed architecture (e.g., a hierarchy).

For example, the fabrication system may include one or more processors, such as the processor 534, one or more memories, such as the memory 535, and/or controllers that are distributed according to the distributed architecture. The distributed architecture may include a high-level processor that controls or initiates operations of one or more low-level systems. For example, a high-level portion of the fabrication process 528 may include one or more processors, such as the processor 534, and the low-level systems may each include or may be controlled by one or more corresponding controllers. A particular controller of a particular low-level system may receive one or more instructions (e.g., commands) from a high-level system, may issue sub-commands to subordinate modules or process tools, and may communicate status data back to the high-level system. Each of the one or more low-level systems may be associated with one or more corresponding pieces of fabrication equipment (e.g., processing tools). In a particular embodiment, the fabrication system may include multiple processors that are distributed in the fabrication system. For example, a controller of a low-level system component of the fabrication system may include a processor, such as the processor 534.

Alternatively, the processor 534 may be a part of a high-level system, subsystem, or component of the fabrication system. In another embodiment, the processor 534 includes distributed processing at various levels and components of a fabrication system.

The die 536 may be provided to a packaging process 538 where the die 536 is incorporated into a representative package 540. For example, the package 540 may include the single die 536 or multiple dies, such as a system-in-package (SiP) arrangement. The package 540 may be configured to conform to one or more standards or specifications, such as Joint Electron Device Engineering Council (JEDEC) standards.

Information regarding the package 540 may be distributed to various product designers, such as via a component library stored at a computer 546. The computer 546 may include a processor 548, such as one or more processing cores, coupled to a memory 550. A printed circuit board (PCB) tool may be stored as processor executable instructions at the memory 550 to process PCB design information 542 received from a user of the computer 546 via a user interface 544. The PCB design information 542 may include physical positioning information of a packaged electronic device on a circuit board, the packaged electronic device corresponding to the package 540 including the SRAM bit cell 114, an array of bit cells having one or more strapped contacts manufactured according to a sub-16 nm technology node, or any other semiconductor device having a strapped contact manufactured according to a sub-16 nm technology node.

The computer 546 may be configured to transform the PCB design information 542 to generate a data file, such as a GERBER file 552 with data that includes physical positioning information of a packaged electronic device on a circuit board, as well as layout of electrical connections such as traces and vias, where the packaged electronic device corresponds to the package 540 including the SRAM bit cell 114, an array of bit cells having one or more strapped contacts manufactured according to a sub-16 nm technology node, or any other semiconductor device having a strapped contact manufactured according to a sub-16 nm technology node. In other embodiments, the data file generated by the transformed PCB design information may have a format other than a GERBER format.

The GERBER file 552 may be received at a board assembly process 554 and used to create PCBs, such as a representative PCB 556, manufactured in accordance with the design information stored within the GERBER file 552. For example, the GERBER file 552 may be uploaded to one or more machines to perform various steps of a PCB production process. The PCB 556 may be populated with electronic components including the package 540 to form a representative printed circuit assembly (PCA) 558.

The PCA 558 may be received at a product manufacturer 560 and integrated into one or more electronic devices, such as a first representative electronic device 562 and a second representative electronic device 564. As an illustrative, non-limiting example, the first representative electronic device 562, the second representative electronic device 564, or both, may be selected from a mobile phone, a tablet, a communications device, a personal digital assistant (PDA), a music player, a video player, an entertainment unit, a navigation device, a fixed location data unit, and a computer, into which the SRAM bit cell 114, an array of bit cells having one or more strapped contacts manufactured according to a sub-16 nm technology node, or any other semiconductor device having a strapped contact manufactured according to a sub-16 nm technology node, is integrated. As another illustrative, non-limiting example, one or more of the electronic devices 562 and 564 may be remote units such as hand-held personal communication systems (PCS) units, portable data units such as personal data assistants, global positioning system (GPS) enabled devices, or any other device that stores or retrieves data or computer instructions, or any combination thereof Although FIG. 5 illustrates remote units according to teachings of the disclosure, the disclosure is not limited to these illustrated units. Embodiments of the disclosure may be suitably employed in any device which includes active integrated circuitry including memory and on-chip circuitry.

A device that includes the SRAM bit cell 114, an array of bit cells having one or more strapped contacts manufactured according to a sub-16 nm technology node, or any other semiconductor device having a strapped contact manufactured according to a sub-16 nm technology node, may be fabricated, processed, and incorporated into an electronic device, as described in the illustrative manufacturing process 500. One or more aspects of the embodiments disclosed with respect to FIG. 1A-FIG. 4 may be included at various processing stages, such as within the library file 512, the GDSII file 526, and the GERBER file 552, as well as stored at the memory 510 of the research computer 506, the memory 518 of the design computer 514, the memory 550 of the computer 546, the memory of one or more other computers or processors (not shown) used at the various stages, such as at the board assembly process 554, and also incorporated into one or more other physical embodiments such as the mask 532, the die 536, the package 540, the PCA 558, other products such as prototype circuits or devices (not shown), or any combination thereof The process 500 of FIG. 5 may be performed by a single entity or by one or more entities performing various stages of the manufacturing process 500.

In conjunction with the described aspects, an apparatus includes means for patterning a first photo resist to apply a first pattern to a hard mask. For example, the means for patterning the first photo resist may include one or more components of the manufacturing equipment described with respect to FIG. 5, such as the EDA tool 520, the design computer 514, the GDSII file 526, etc.

The apparatus also includes means for patterning a second photo resist to apply a second pattern to a hard mask. For example, the means for patterning the second photo resist may include one or more components of the manufacturing equipment described with respect to FIG. 5, such as the EDA tool 520, the design computer 514, the GDSII file 526, etc.

The apparatus also includes means for etching a first trench and a second trench through an interlayer dielectric. For example, the means for etching the first trench and the second trench may include one or more components of the manufacturing equipment described with respect to FIG. 5, such as the components of the fabrication process 528.

The apparatus also includes means for depositing metal into the first trench to form a first contact. For example, the means for depositing metal in the first trench may include one or more components of the manufacturing equipment described with respect to FIG. 5, such as the components of the fabrication process 528.

The apparatus also includes means for depositing metal into the second trench to form a second contact. For example, the means for depositing metal into the second trench may include one or more components of the manufacturing equipment described with respect to FIG. 5, such as the components of the fabrication process 528.

The apparatus also includes means for forming a strapped contact that is coupled to the first contact and to the second contact. For example, the means for forming the strapped contact may include one or more components of the manufacturing equipment described with respect to FIG. 5, such as the EDA tool 520, the design computer 514, the GDSII file 526, the mask 532, components of the fabrication process 528, etc.

Those of skill would further appreciate that the various illustrative logical blocks, configurations, modules, circuits, and algorithm steps described in connection with the embodiments disclosed herein may be implemented as electronic hardware, computer software, or combinations of both. Various illustrative components, blocks, configurations, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the embodiments disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of storage medium known in the art. An exemplary non-transitory (e.g. tangible) storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal In the alternative, the processor and the storage medium may reside as discrete components in a computing device or user terminal.

The previous description of the disclosed embodiments is provided to enable a person skilled in the art to make or use the disclosed embodiments. Various modifications to these embodiments will be readily apparent to those skilled in the art, and the principles defined herein may be applied to other embodiments without departing from the scope of the disclosure. Thus, the present disclosure is not intended to be limited to the embodiments shown herein but is to be accorded the widest scope possible consistent with the principles and novel features as defined by the following claims.

What is claimed is:

1. An apparatus comprising:
a first fin of a first transistor;
a second fin of a second transistor;
a first contact coupled to the first fin;
a second contact coupled to the second fin; and
a strapped contact coupled to the first contact and to the second contact.

2. The apparatus of claim 1, wherein the first transistor and the second transistor are manufactured using a semiconductor manufacturing process of less than 16 nanometers (nm).

3. The apparatus of claim 2, wherein the semiconductor manufacturing process is a 10 nm process.

4. The apparatus of claim 2, wherein the semiconductor manufacturing process is a 7 nm process.

5. The apparatus of claim 1, wherein the first transistor and the second transistor are included in a logic circuit.

6. The apparatus of claim 5, wherein the logic circuit includes a static random access memory (SRAM) bit cell.

7. The apparatus of claim 1, wherein the first fin and the second fin are comprised of silicon.

8. The apparatus of claim 1, wherein the first contact, the second contact, and the strapped contact are comprised of tungsten, copper, silicide, or any other metal.

9. The apparatus of claim 1, wherein the first transistor and the second transistor are integrated into at least one semiconductor device.

10. The apparatus of claim 1, further comprising a device selected from the group consisting of a mobile phone, a personal digital assistant (PDA), a tablet, a music player, a video player, an entertainment unit, a navigation device, a communications device, a fixed location data unit, and a computer, into which the first transistor and the second transistor are integrated.

11. A method for forming contacts in a semiconductor device that is manufactured using a semiconductor manufacturing process of less than 16 nanometers (nm), the method comprising:
patterning a first photo resist to apply a first pattern to a hard mask, the first pattern designed to expose a first fin of a first transistor;
patterning a second photo resist to apply a second pattern to the hard mask, the second pattern designed to expose a second fin of a second transistor;
etching a first trench through an interlayer dielectric according to the first pattern to expose the first fin;
etching a second trench through the interlayer dielectric according to the second pattern to expose the second fin;
depositing metal into the first trench to form a first contact;
depositing metal into the second trench to form a second contact; and
forming a strapped contact that is coupled to the first contact and to the second contact.

12. The method of claim 11, wherein the semiconductor manufacturing process is a 10 nm process.

13. The method of claim 11, wherein the semiconductor manufacturing process is a 7 nm process.

14. The method of claim 11, wherein forming the strapped contact comprises:
patterning a mask to etch a third trench through the interlayer dielectric to the first contact and to the second contact; and
depositing metal into the third trench to form the strapped contact.

15. The method of claim 11, further comprising performing a planarization process to smooth the first contact and the second contact prior to forming the strapped contact.

16. The method of claim 11, wherein the first transistor and the second transistor are included in a logic circuit.

17. The method of claim 16, wherein the logic circuit includes a static random access memory (SRAM) bit cell.

18. The method of claim 11, wherein the first fin and the second fin are comprised of silicon.

19. The method of claim 11, wherein the first contact, the second contact, and the strapped contact are comprised of tungsten, copper, silicide, or any other metal.

20. The method of claim 11, wherein patterning the first photo resist and patterning the second photo resist are initiated at a processor integrated into an electronic device.

21. A non-transitory computer-readable medium comprising instructions for forming contacts in a semiconductor device that is manufactured using a semiconductor manufacturing process of less than 16 nanometers (nm), the instructions, when executed by a processor, cause the processor to:
initiate patterning a first photo resist to apply a first pattern to a hard mask, the first pattern designed to expose a first fin of a first transistor;
initiate patterning a second photo resist to apply a second pattern to the hard mask, the second pattern designed to expose a second fin of a second transistor;
initiate etching a first trench through an interlayer dielectric according to the first pattern to expose the first fin;
initiate etching a second trench through the interlayer dielectric according to the second pattern to expose the second fin;
initiate depositing metal into the first trench to form a first contact;
initiate depositing metal into the second trench to form a second contact; and
initiate forming a strapped contact that is coupled to the first contact and to the second contact.

22. The non-transitory computer-readable medium of claim 21, wherein the semiconductor manufacturing process is a 10 nm process.

23. The non-transitory computer-readable medium of claim 21, wherein the semiconductor manufacturing process is a 7 nm process.

24. The non-transitory computer-readable medium of claim 21, wherein forming the strapped contact comprises:
patterning a mask to etch a third trench through the interlayer dielectric to the first contact and to the second contact; and
depositing metal into the third trench to form the strapped contact.

25. The non-transitory computer-readable medium of claim 21, further comprising instructions that, when executed by the processor, cause the processor to initiate a planarization process to smooth the first contact and the second contact prior to forming the strapped contact.

26. The non-transitory computer-readable medium of claim 21, wherein the first transistor and the second transistor are integrated into a mobile phone, a personal digital assistant (PDA), a tablet, a music player, a video player, an entertainment unit, a navigation device, a communications device, a fixed location data unit, or a computer.

27. An apparatus comprising:
means for patterning a first photo resist to apply a first pattern to a hard mask, the first pattern designed to expose a first fin of a first transistor;
means for patterning a second photo resist to apply a second pattern to the hard mask, the second pattern designed to expose a second fin of a second transistor;
means for etching a first trench through an interlayer dielectric according to the first pattern to expose the first fin;
means for etching a second trench through the interlayer dielectric according to the second pattern to expose the second fin;
means for depositing metal into the first trench to form a first contact;
means for depositing metal into the second trench to form a second contact; and
means for forming a strapped contact that is coupled to the first contact and to the second contact.

28. The apparatus of claim 27, wherein the first transistor and the second transistor are manufactured using a semiconductor manufacturing process of less than 16 nanometers (nm).

29. The apparatus of claim 28, wherein the semiconductor manufacturing process is a 10 nm process.

30. The apparatus of claim 28, wherein the semiconductor manufacturing process is a 7 nm process.
